(19) United States
(12) Patent Application Publication
(10) Pub. No.: US 2020/0096863 A1
(43) Pub. Date: Mar. 26, 2020

(54) METHOD OF FLUID DROPLET OFFSET AND APPARATUS FOR IMPRINT LITHOGRAPHY

(71) Applicant: CANON KABUSHIKI KAISHA, Tokyo (JP)

(72) Inventors: Ozkan Ozturk, Round Rock, TX (US); Alireza Aghili, Austin, TX (US); Edward Brian Fletcher, Austin, TX (US)

(21) Appl. No.: 16/141,087

(22) Filed: Sep. 25, 2018

(51) Int. Cl. G03F 7/00; B41J 3/54

(52) U.S. Cl. CPC G03F 7/0002; B82Y 10/00; B41J 3/543

(57) ABSTRACT

An apparatus for imprint lithography is disclosed. The apparatus may include a fluid dispense head comprising at least two fluid dispense ports in a fixed arrangement relative to one another. The fluid dispense head can moves relative to the substrate in a translating direction. The apparatus may further include a logic element configured to determine a substrate fluid droplet pattern. The apparatus can dispense the formable material form a first part of the substrate fluid droplet pattern. The apparatus may be configured to move the fluid dispense head in an offset direction after an instruction to dispense the formable material is executed. The apparatus may dispense the formable material to form a second part of the substrate fluid droplet pattern. The first part of the fluid droplet pattern and the second part of the fluid droplet pattern can be dispensed during a first pass.

### FIELD OF THE DISCLOSURE

The present disclosure relates to substrate processing, and more particularly to fluid droplet patterning in semiconductor fabrication.

### RELATED ART

Imprint lithography apparatuses and processes are useful in forming nanoscale patterns on semiconductor wafers in the fabrication of electronic devices. Such apparatuses and processes can include the use of fluid dispense systems for depositing a formable material, for example, a polymerizable material, such as a resin or a resist, onto the substrate, using techniques such as fluid droplet dispense. The dispensed material is contacted with an imprint template (or mold) having desired pattern features and then solidified, forming a patterned layer on the substrate. Template feature fill rates and related defects are dependent, in part, on template pattern feature density and orientation and the droplet pattern arrangement, including fluid droplet pitch.

Traditional fluid dispense systems are limited by the rate at which the fluid can be dispensed as well as by the spacing of fluid dispense ports on the fluid dispense head. There continues to be an industry demand for droplet pattern processes which are more finely adjustable and which are not limited by dispenser limitations.

### SUMMARY OF THE INVENTION

In an aspect, an apparatus for imprint lithography is disclosed. The apparatus may include a fluid dispense head comprising at least two fluid dispense ports. The at least two fluid dispense ports can be in a fixed arrangement relative to one another. The apparatus may also include a stage configured to hold a substrate. The stage and the fluid dispense head can be adapted to move the substrate and the at least two fluid dispense ports relative to each other. The apparatus may further include a logic element configured to determine a substrate fluid droplet pattern for dispensing a formable material onto the substrate and transmit information to dispense the formable material onto the substrate to form a first part of the substrate fluid droplet pattern. The fluid dispense head can move relative to the substrate in a translating direction. The logic element may be further configured to transmit information to move the fluid dispense head relative to the substrate in an offset direction. The apparatus may be configured to move the fluid dispense head after an instruction to dispense the formable material is executed. The logic element may be further configured to transmit information to dispense the formable material onto the substrate to form a second part of the substrate fluid droplet pattern. The apparatus can be configured to dispense the formable material after an instruction to move the fluid dispense head is executed. The first part of the fluid droplet pattern and the second part of the fluid droplet pattern can be dispensed during a first pass.

In another aspect, the logic element may further include determining the offset direction to achieve the second fluid droplet pattern.

In another aspect, the offset direction and the translating direction can be in one plane.

In another aspect, the offset direction can be in one plane and the translating direction can be in a second plane.

In another aspect, during dispensing, the fluid dispense head can be oriented along a plane that is parallel to a surface of the substrate.

In another aspect, the at least two dispense ports can have a fixed firing speed.

In another aspect, determining a substrate fluid drop pattern can be for an imprint field.

In another aspect, the apparatus may further include a substrate holder configured to hold the substrate.

In another aspect, a method of generating a fluid droplet pattern may be disclosed. The method may include providing a fluid dispense head comprising at least two dispense ports. The at least two fluid dispense ports can be in a fixed arrangement relative to one another. The method of generating a fluid droplet pattern may further include determining a substrate fluid droplet pattern for dispensing a formable material onto a substrate, moving the fluid dispense head relative to a substrate in a translating direction while the fluid dispense ports remain in a fixed arrangement, dispensing formable material onto the substrate to form a first part of the substrate fluid droplet pattern, moving the fluid dispense head in an offset direction perpendicular to the translating direction, and dispensing formable material onto the substrate to form a second part of the substrate fluid droplet pattern. The first part of the fluid droplet pattern and the second part of the fluid droplet pattern can be dispensed during a first pass.

In another aspect, the method of generating a fluid droplet pattern may further include determining the offset direction to achieve the second fluid droplet pattern.

In another aspect of the method, the fluid dispense head can be oriented along a plane that is parallel to a surface of the substrate.

In another aspect of the method, the offset direction and the translating direction can be in one plane.

In another aspect of the method, the offset direction is in one plane and the translating direction is in a second plane.

In another aspect of the method, determining a substrate fluid drop pattern can be for an imprint field.

In another aspect of the method, the at least two dispense ports can have a fixed firing speed.

In another aspect, a method of manufacturing an article may be disclosed. The method of manufacturing an article may include providing a fluid dispense head comprising a set of fluid dispense ports. The fluid dispense ports can be in a fixed arrangement relative to one another. The method of manufacturing an article may also include determining a substrate fluid droplet pattern for dispensing a formable material onto a substrate, moving the fluid dispense head relative to a substrate in a translating direction while the fluid dispense ports remain in a fixed arrangement, dispensing formable material onto the substrate to form a first part of the substrate fluid droplet pattern, moving the fluid dispense head in an offset direction perpendicular to the translating direction, and dispensing formable material onto the substrate to form a second part of the substrate fluid droplet pattern. The first part of the fluid droplet pattern and the second part of the fluid droplet pattern can be dispensed during a first pass. The method of manufacturing an article may also include contacting the formable material with a template having a surface and curing the formable material to form a layer corresponding to the surface of the template.

In another aspect of the method of manufacturing an article, the offset direction and the translating direction can be in one plane.

In another aspect of the method of manufacturing an article, the offset direction can be in one plane and the translating direction can be in a second plane.

In another aspect of the method of manufacturing an article, determining a substrate fluid drop pattern can be for an imprint field.

In another aspect of the method of manufacturing an article, the article may include an electronic device, and the substrate may include a semiconductor wafer.

In yet another aspect a method of generating a fluid droplet pattern is disclosed. The method includes providing a fluid dispense head comprising at least two dispense ports. The at least two fluid dispense ports can be in a fixed arrangement relative to one another. The method can further include while moving the fluid dispense head and the substrate relative to each other in a translating direction, the following steps are performed: dispensing formable material onto the substrate to form a first part of the substrate fluid droplet pattern, moving the fluid dispense head in an offset direction different from the translating direction to change a distance between the fluid dispense head and the substrate after forming the first part of the substrate fluid droplet pattern, and dispensing formable material onto the substrate to form a second part of the substrate fluid droplet pattern after moving the fluid dispense head in an offset direction. A pitch between the first part and the second part of the fluid droplet pattern can be changed by changing the distance between the fluid dispense head and the substrate

### BRIEF DESCRIPTION OF THE DRAWINGS

Embodiments are illustrated by way of example and are not limited in the accompanying figures.

FIG. 1 includes an illustration of a side view of an exemplary imprint lithography system.

FIG. 2 includes a fluid droplet pattern in which the fluid dispense head is movable in the X-direction.

FIG. 3 includes a fluid droplet pattern in which the dispense head is movable in accordance to one embodiment of the present disclosure.

FIG. 4 includes a fluid droplet pattern in which the fluid dispense head is movable in accordance to another embodiment of the present disclosure.

FIG. 5 includes a fluid droplet pattern in in which the fluid dispense head is movable in accordance to another embodiment of the present disclosure.

FIG. 6 shows a method of generating a fluid droplet pattern in accordance to one embodiment of the present disclosure.

Skilled artisans appreciate that elements in the figures are illustrated for simplicity and clarity and have not necessarily been drawn to scale. For example, the dimensions of some of the elements in the figures may be exaggerated relative to other elements to help improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings.

A fluid droplet pattern may refer to an actual pattern that physically exists or will exist or a virtual pattern that can be computer generated representation of fluid droplet pattern. The term “substrate fluid droplet pattern” refers to a particular actual pattern of fluid droplets as formed on a substrate. An “adjusted fluid droplet pattern” refers to a particular virtual droplet pattern, and in an embodiment, such virtual droplet pattern can correspond to the substrate fluid droplet pattern produced when using the adjusted fluid droplet pattern.

The term “pitch” is intended to mean a distance from a center of a feature to a center of a next adjacent feature. For a fluid droplet pattern, the pitch is a distance from the center of a droplet to the center of the next adjacent droplet. In Cartesian coordinates, a two-dimensional pattern (a pattern as seen from a top or plan view) can have a pitch in the X-direction that corresponds to the distance between the centers of the features as measured in the X-direction (X-direction pitch), and a pitch in the Y-direction that corresponds to the distance between the centers of the features as measured in the Y-direction (Y-direction pitch). The X-direction pitch may be the same or different from the Y-direction pitch.

As used herein, speed and motion may be described on a relative basis. For example, object A and object B move relative to each other. Such terminology is intended to cover object A is moving, and object B is not; object A is not moving, and object B is moving; and both of objects A and B are moving.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

In imprint lithography, the formable material needs to be dispensed in a controlled matter to ensure that a proper amount of formable material is dispensed in correct locations and areal densities on the substrate. Centers of fluid droplets closest to the edges of the imprint field are placed such that, during an imprint operation, a proper amount of formable material can flow toward the edge of the imprint field. If the fluid droplets are too close to the edge, a portion of the formable material can flow beyond an edge of the imprint lithography template, and such portion of the formable material can upon curing, adhere to the template and lead to extrusion defects. That is, during subsequent imprinting, the adhered material can detach from the template and contaminate the subsequently imprinted layer, causing a defect in subsequent pattern transfer processes which can ultimately effect device yield. If the fluid droplets are too far from the edge, incomplete filling of template features may occur. Such defects are called “non-fill” defects and translate to a loss of features upon pattern transfer. Extrusion defects and non-fill defects are undesired.

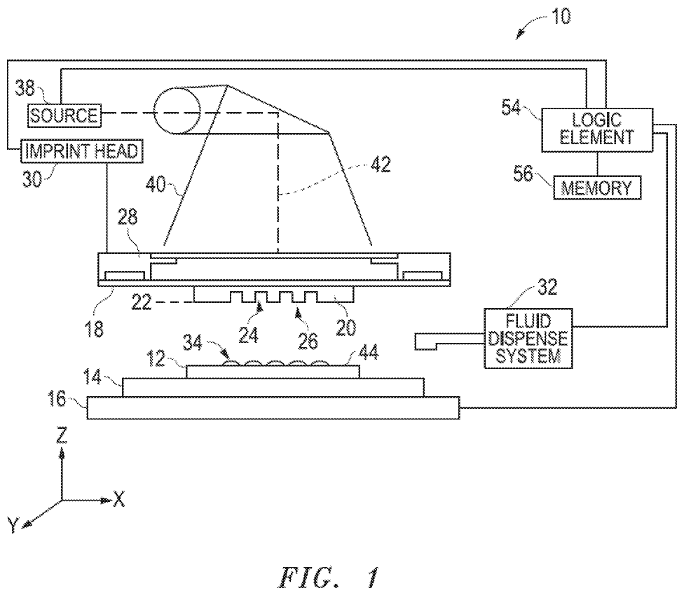

Referring to FIG. 1, an apparatus 10 in accordance with an embodiment described herein can be used in depositing formable material over a substrate 12 in preparation for patterning or planarization. The substrate 12 may be a semiconductor base material, such as a silicon wafer, but may include an insulating base material, such as glass, sapphire, spinel, or the like. The substrate 12 may be coupled to a substrate holder 14. The substrate holder 14 may be a vacuum chuck; however, in other embodiments the substrate holder 14 may be any chuck including vacuum, pin-type, groove-type, electrostatic, electromagnetic, or the like. Exemplary chucks are described in U.S. Pat. No. 6,873,087, which is hereby incorporated by reference in its entirety herein. The substrate 12 and substrate holder 14 may be further supported by a stage 16. The stage 16 may provide translating or rotational motion along the X-, Y-, or Z-directions. The stage 16, substrate 12, and substrate chuck 14 may also be positioned on a base (not illustrated).

Spaced-apart from the substrate 12 may be a template 18. The template 18 can be coupled to a holder 28. Exemplary holders or chucks are further described in U.S. Pat. No. 6,873,087, herein incorporated by reference. In an embodiment, the holder 28 may be coupled to an imprint head 30 such that the holder 28 or imprint head 30 can facilitate movement of the template 18. The template 18 can include a body having a first side and a second side with one side having a mesa 20 extending therefrom towards the substrate 12. The mesa 20 is sometimes referred to as a mold 20. In an embodiment, the template 18 can be formed without a mesa 20. The template 18 may be both held by and its shape modulated by the holder 28. In one embodiment, the holder 28 may include a pressure system (not shown) to aid in holding and modulating the template 18. The superstrate holder 28 can be configured as vacuum, pin-type, groove-type, electrostatic, electromagnetic, or another similar holder type. In an embodiment, the superstrate holder 28 may be coupled to an imprint head 30 such that the superstrate holder 28 or imprint head 30 can facilitate translation or rotational motion of the template 18 along the X-, Y-, or Z-directions.

The template 18 or mesa 20 may be formed from such materials including a glass-based material, fused-silica, quartz, silicon, organic polymers, siloxane polymers, borosilicate glass, fluorocarbon polymers, metal, hardened sapphire, a spinel, other similar materials, or any combination thereof. The glass-based material can include soda lime glass, borosilicate glass, alkali-barium silicate glass, aluminosilicate glass, quartz, synthetic fused-silica, or the like. The template 18 can include a deposited oxide, anodized alumina, an organo-silane, an organosilicate material, an organic polymer, inorganic polymers, and any combination thereof. The template 18 can have a thickness in a range of 20 microns to 6.5 mm. The template 18 and mesa 20 can include a single piece construction. Alternatively, the template 18 and mesa 20 can include separate components coupled together. In one embodiment, the mesa 20 can have a thickness between 20 microns and 40 microns. As illustrated, a patterning surface 22 includes features defined by spaced-apart recesses 24 and protrusions 26. The disclosure is not intended to be limited to such configurations (e.g., planar surfaces). The patterning surface 22 may define any original pattern that forms the basis of a pattern to be formed on the substrate 12. In another embodiment, the patterning surface 22 can be a blank, that is, the patterning surface 22 does not have any recesses or projections.

The apparatus 10 can further include a fluid dispense system 32 used to deposit a formable material 34 on the substrate 12. For example, the formable material can include a polymerizable material, such as a resin. The formable material 34 can be positioned on the substrate 12 in one or more layers using techniques such as droplet dispense, spin-coating, dip coating, chemical vapor deposition (CVD), physical vapor deposition (PVD), thin film deposition, thick film deposition, or combinations thereof. The formable material 34 can be dispensed upon the substrate 12 before or after a desired volume is defined between the mold 20 and the substrate 12 depending on design considerations. For example, the formable material 34 can include a monomer mixture as described in U.S. Pat. Nos. 7,157,036 and 8,076,386, both of which are herein incorporated by reference in their entireties.

The apparatus 10 can further include an energy source 38 coupled to a direct energy 40 along a path 42. The imprint head 30 and stage 16 can be configured to position the template 18 and substrate 12 in superimposition with the path 42. The apparatus 10 can be regulated by a logic element 54 in communication with the stage 16, imprint head 30, fluid dispense system 32, or source 38, and may operate on a computer readable program, optionally stored in memory 56.

In an embodiment, either the imprint head 30, the stage 16, or both the imprint head 30 and the stage 16 vary a distance between the mold 20 and the substrate 12 to define a desired volume therebetween that is filled by the formable material 34. For example, the imprint head 30 can apply a force to the template 18 such that the mold 20 contacts the formable material 34 on the substrate 12. After the desired volume is filled with the formable material 34, the source 38 can produce energy 40, e.g., ultraviolet radiation, causing the formable material 34 to solidify or cross-link conforming to a shape of the surface 44 of the substrate 12.

High throughput at low defect density is an important consideration in imprint lithography processes. When employing a droplet dispense method of applying the formable material to the substrate 12, the imprint process cycle generally includes (1) dispensing (or depositing) fluid droplets of formable material on a substrate surface, (2) bringing a template into contact with the fluid droplets such that the fluid spreads and fills the topography of the template patterning surface, (3) solidifying (e.g., photocuring) the fluid, and (4) separating the template from the substrate 12, leaving a solidified layer of formable material having a relief image of the template pattern on the substrate surface. Dispensing fluid droplets of formable material on the substrate surface and proper filling of the pattern of the template 18 are major contributors to the imprint cycle time, and thus throughput. Particular template patterns may require multiple passes of the substrate 12 relative to the imprint head 30. That is, the substrate 12 and imprint head 30 must be translated relative to each other multiple times. Multiple dispensing passes are common, for example, when templates have dense feature patterns or for particular patterns requiring adjacent droplets be positioned closer together. Methods and systems to reduce dispense time are described in accordance with one or more embodiments described herein.

During dispensing, fluid droplets of formable material are dispensed from the fluid dispense system 32 to create a pattern of fluid droplets on the substrate surface 44. The fluid droplet pattern can be determined such that the total volume of the fluid droplets on the surface matches the total volume for the desired fluid droplet pattern. As well as matching the total volume of the desired fluid droplet pattern, it may be desirable to match the local volume of the desired fluid droplet pattern. Thus, a greater volume of fluid can be dispensed in a region of the substrate 12 where a greater volume of formable material is desired.

Available inkjet systems can be tuned to dispense formable material fluid droplets with volumes in the range of 0.1 to 10 picoliters (pL) or greater, with 0.9 pL being an exemplary fluid droplet volume. The fluid droplets can be dispensed in patterns formed by one or more passes of the imprint head 30 and substrate 12 relative to one another. An exemplary pattern includes a rectangular grid pattern, a diamond pattern, another suitable pattern, or any combination thereof.

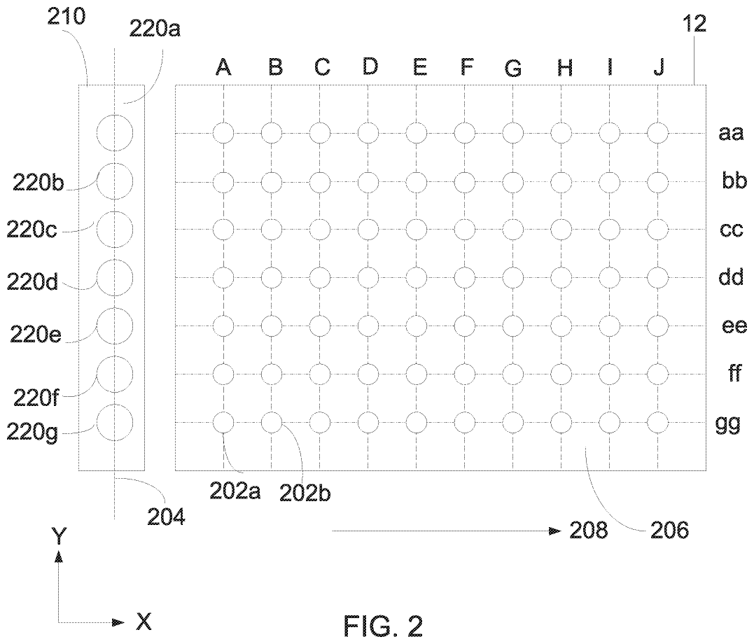

Referring to FIG. 2, the fluid dispense system 32 can include fluid dispense head 210 and fluid dispense ports 220. The fluid dispense ports 220 may be in a fixed configuration such that the fluid dispense head 210 and fluid dispense ports 220 move as a unit and do not move independent of each other. In other words, the fluid dispense ports 220 are fixed relative to one another on the fluid dispense head 210. As illustrated, the fluid dispense system 32 includes seven fluid dispense ports 220a, 220b, 220c, 220d, 220e, and 220f; however, the number of fluid dispense ports 220 can be less than or greater than six, such as for example, at least two fluid dispense ports, at least three fluid dispense ports, at least four fluid dispense ports, at least five fluid dispense ports, at least ten fluid dispense ports, or at least twenty fluid dispense ports. In an embodiment, the fluid dispense ports 220 can include a set of at least three fluid dispense ports (e.g., fluid dispense ports 220a, 220b, and 220c) lying along a straight line 204. In traditional dispensing operations of formable material, a Y-direction pitch is fixed by a distance between centers of adjacent fluid dispense ports, and therefore, the Y-direction pitch is determined by the physical layout of the fluid dispense ports 220 in the fluid dispense head.

The fluid dispense system 32 and a surface 206 located there below (e.g., on the substrate 12 or the substrate chuck 14) can be moveable in a translating direction (illustrated by arrow 208). Fluid droplets, including fluid droplets 202a and 202b, can be dispensed from the fluid dispense ports 220 onto the surface 206 in rows aa-gg and columns A-J. In the embodiment of FIG. 2, fluid droplet 202a intersects both column A and row gg and fluid droplet 202b intersects both column B and row gg. As will be discussed in more detail below, the fluid droplets 202a and 202b can intersect the same row, different rows, different columns, no columns, no rows, or combinations thereof.

A fluid dispense head 210 (and the control software that operates it) has preset parameters (hereinafter “presets”) that can limit the flexibility of the fluid dispense system. The fluid dispense head can have a preset firing frequency that is programmed to produce a preset minimum pitch (X-direction pitch in the embodiment illustrated) when the substrate 12 is translated at a preset scan speed in the X-direction. In one embodiment, the preset firing frequency is the maximum speed allotted by the manufacturing parameters for the fluid dispense ports. In another embodiment, the preset firing frequency is the minimum speed allotted by the manufacturing parameters for the fluid dispense ports. Accordingly, only a limited number of fluid droplet patterns can be produced based on locations on a corresponding X-Y grid. The limitations on the fluid dispense port pitch and presets of the apparatus can allow a less-than ideal droplet pattern.

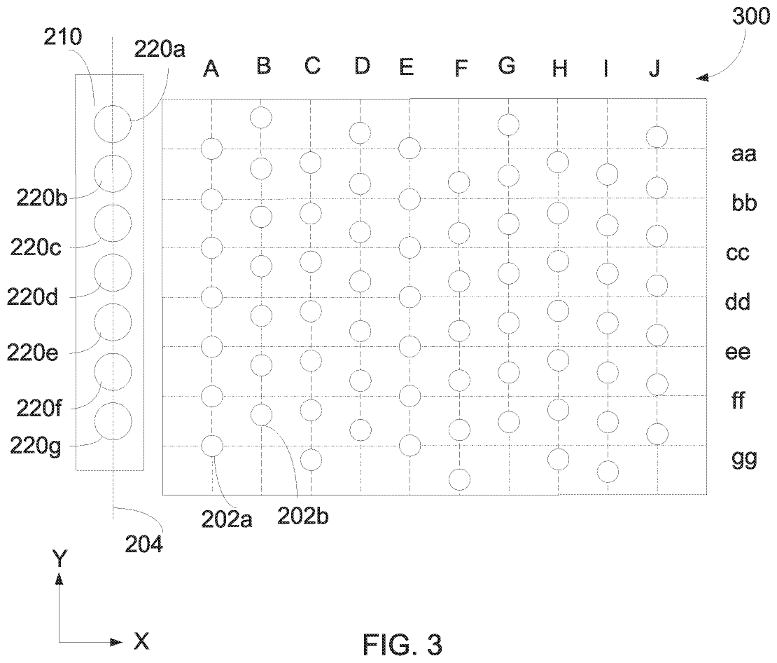

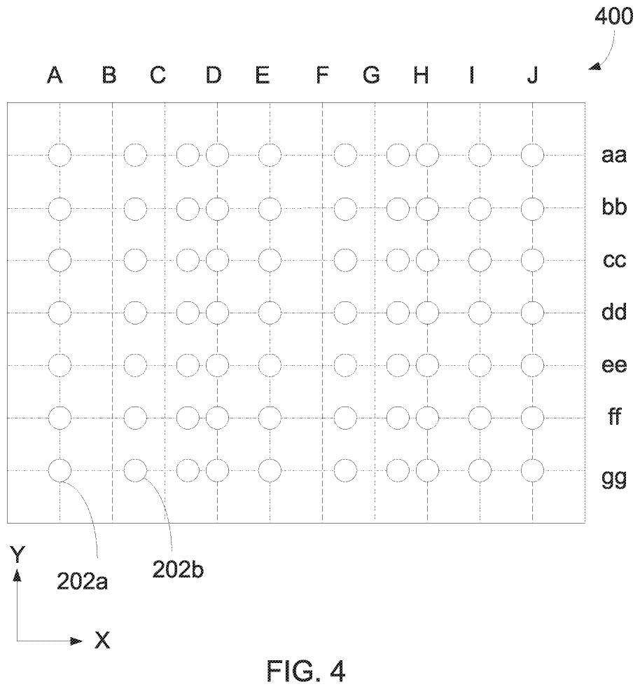

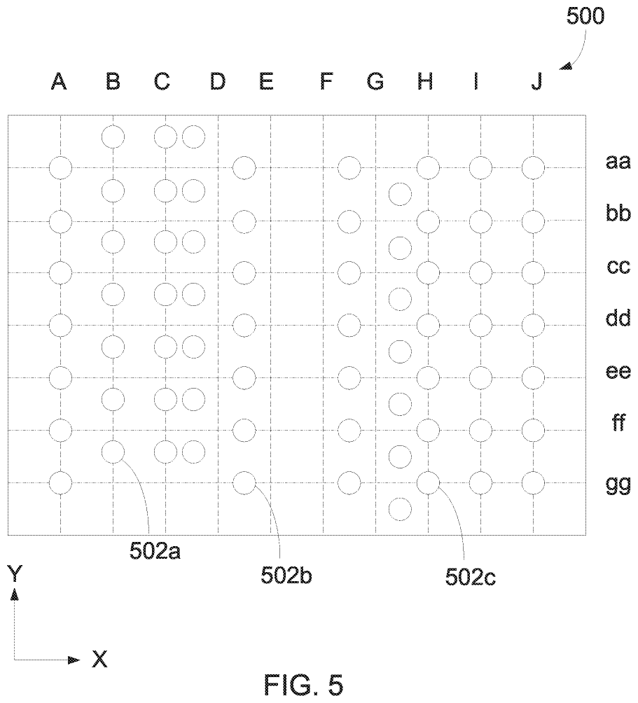

In an embodiment, within the same pass in dispensing the formable material, the fluid dispense ports 220 can be offset in an offset direction for an offset distance. The offset direction can be substantially perpendicular to the translating direction 208. In the embodiment of FIG. 3, the offset direction is on the same plane as the translating direction. As such, the offset direction is in the Y direction. In the embodiment of FIG. 4, the offset direction is on a different plane than the translating direction. As such, the offset direction in FIG. 4 is in the Z-direction. In yet another embodiment of FIG. 5, the offset direction can be on the same plane for one column and on a different plane for a second column. As used herein, substantially perpendicular means±10° of perpendicular, and substantially parallel means±10° of parallel. More detail regarding the offset is provided below.

FIG. 3 includes a fluid droplet pattern 300 in which the dispense head 210 is movable in the X-direction and Y-direction. The fluid dispense ports 220a-220g can be fixed to the dispense head 210, and the firing rate of the fluid dispense ports can be at a fixed speed. The fluid dispense head 210 can move in an offset direction relative the substrate 12 for a distance about half the pitch of the fluid dispense port. In one embodiment, the offset amount relative the substrate can be between 1 nm to 10 mm. In one embodiment, the offset amount relative the substrate can be no greater than 10 mm, such as 9 mm, no greater than 8 mm, no greater than 7 mm, no greater than 6 mm, no greater than 5 mm, no greater than 4 mm, no greater than 3 mm, no greater than 2 mm, or no greater than 1.5 mm. As such droplets can be placed in between rows at various distances. As seen in FIG. 3, one part of the droplet pattern can be closer to one edge of the substrate, column B, while a second part of the droplet pattern can be closer to a second edge of the substrate opposite the first edge of the substrate, column F. By moving the fluid dispense head 210 in the offset direction, Y direction, the pitch of drops, normally limited by the distance between each of the nozzles, can be altered to be less than the distance of the nozzles. In one embodiment, the fluid dispense head places a first set of drops that intersects both columns and rows, for example column A. The fluid dispense head 210 can place a second set of droplets of formable material on the substrate that intersects a column but does not intersect any rows, column B. The first set of droplets, column A, and the second set of droplets, column B can be dispensed in a single pass as the fluid dispense head 210 and the substrate 12 move relative to each other in a translating direction 208. In one embodiment, the fluid dispense head 210 moves in both the translating direction and offset direction while the substrate 12 remains stationary. In another embodiment, the fluid dispense head 210 moves in a diagonal direction—being the summation of moving in both the translating direction and offset direction—while the substrate 12 remains stationary. In another embodiment, the fluid dispense head 210 moves in the offset direction while the substrate 12 moves in the translating direction. In yet another embodiment, the fluid dispense head 210 moves in the translating and offset direction while the substrate also moves in the translating direction, but where when moving in the translating directions, the fluid dispense head 210 and the substrate 12 are moving at different speeds. In the embodiment of FIG. 3, droplet 202a intersects both a column and a row while droplet 202b intersects a column but no rows.

FIG. 4 includes a fluid droplet pattern 400 in which the fluid dispense head 210 is movable in the X-direction and Z-direction. The fluid dispense head 210 is configured to achieve additional coverage or alternate fluid droplet patterns beyond the coverage seen when the manufacturing equipment or software programming has reached its limits. For example, the fluid dispense head can have a preset firing frequency and that is programmed to produce a preset minimum pitch (X-direction pitch as seem in FIG. 2) when the substrate 12 is translated at a preset scan speed in the X-direction. In one embodiment, the preset firing frequency is the maximum speed allotted by the manufacturing parameters for the fluid dispense ports or the speed at which the stage can be moved in the translating direction. The fluid dispense head 210 is configured to move in an offset direction perpendicular to the translating direction, where the offset direction and translating direction are on a different plane (the Z-direction). By moving the fluid dispense head up and down, the pitch in the X-direction can be further adjusted. Even a system that can alternate the firing speed has a maximum firing frequency. As such, the fluid dispense head can be adjusted in the Z-direction to achieve a droplet pitch in the X-direction beyond the limits of or maximum of firing frequency. In one embodiment, one part of the droplet pattern can be closer to one edge of the substrate while a second part of the droplet pattern can be closer to a second edge of the substrate opposite the first edge of the substrate. By moving the fluid dispense head 210 in the offset direction, Z direction, away from the substrate, the pitch of drops, normally limited by the firing frequency, can be altered to be more than the firing frequency of the fluid dispenses system. In another embodiment, by moving the fluid dispense head 210 in the offset direction, Z direction, towards the substrate, the pitch of drops, normally limited by the firing frequency, can be altered to be less than the firing frequency of the fluid dispenses system. As shown in FIG. 4, the droplet pattern can be adjustable across the variable rows such that the spacing between drops in the X-direction is variable. In one example, droplet 202a intersects both column A and row gg while droplet 202b intersects row gg and is spaced between columns B and C. In one embodiment, the column of droplets can be spaced farther apart in the X-direction. In another embodiment, the column of droplets can be spaced closer together in the X-direction, i.e. altering the drop pitch in the X-direction. In one embodiment, between firing a first set and a second set of droplets, the fluid dispense head can be moved up. In another embodiment, between firing a first set and a second set of droplets, the fluid dispense head can be moved down. The distance of the offset direction can be between 10 microns and 250 microns. In one embodiment, the offset direction can be less than 200 microns, such as 175 microns, less than 150 microns, less than 100 microns, less than 50 microns, less than 25 microns, less than 20 microns, or less than 15 microns.

FIG. 5 includes a fluid droplet pattern 500 in which the fluid dispense head can be movable in the X-direction, Y-direction, and Z-direction. As can be seen, the fluid dispense head can be moved in an offset direction on the same plane as the translating direction for the first set of droplets and then moved in an offset direction on a different plane as the translating direction for the second set of droplets. In other words, a logic element may transmit information to dispense the formable material on the substrate to form a first part of the substrate fluid droplet pattern and may then transmit information to dispense the formable material on the substrate to form a second part of the substrate fluid droplet pattern and may then transmit information to dispense the formable material on the substrate to form a third part of the substrate fluid droplet pattern. In one embodiment, in between dispensing the first part of the droplet pattern and dispensing the second part of the droplet pattern, the fluid dispense head may be moved in a first offset direction perpendicular to the translating direction but on the same plane as the translating direction (502a). In another embodiment, in between dispensing the second part of the droplet pattern and dispensing the third part of the droplet pattern, the fluid dispense head may be moved in a second offset direction perpendicular to the translating direction but on a different plane as the translating direction (502b). In yet another embodiment, in between dispensing the second part of the droplet pattern and dispensing the third part of the droplet pattern, the fluid dispense head may be moved in a second offset direction perpendicular to the translating direction on both a different plane and then on the same plane as the translating direction (502c). In other words, in between dispensing the second part of the droplet pattern and dispensing the third part of the droplet pattern, the fluid dispense head may be moved both in the Z-direction and the Y-direction.

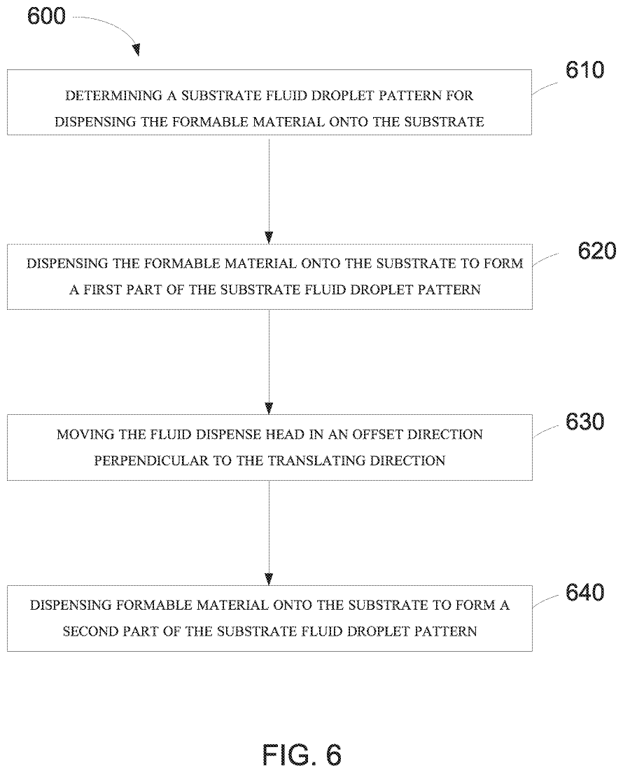

In accordance with an embodiment described herein, FIG. 6 includes a flow chart for a method that can be used forming a substrate fluid droplet pattern for an imprint lithography process that includes an offset between passes of dispensing the fluid droplets. The method can be performed by an imprint lithography apparatus including the fluid dispense system, the fluid dispense ports, the stage, and the logic element of FIGS. 1-5. The logic element can include hardware, firmware, software, or any combination thereof to perform many of the operations described herein. In a particular embodiment, the logic element can be the processor 54. The substrate 12 can be placed on the stage, and in an embodiment, the substrate 12 can be a semiconductor wafer.

The method 600 can include providing a fluid dispense head. The fluid dispense head may include at least two fluid dispense ports, wherein the at least two fluid dispense ports are in a fixed arrangement relative to one another. At block 610, the method can include determining an adjusted fluid droplet pattern for dispensing the formable material onto the substrate. The “adjusted fluid droplet pattern” refers to a particular virtual droplet pattern, and in an embodiment, such virtual droplet pattern can be correspond to the substrate fluid droplet pattern produced when using the adjusted fluid droplet pattern. In one embodiment, the formable material is dispensed using one pass. The substrate 12 is placed and held onto the stage.

At block 620, the method can include dispensing the formable material onto the substrate to form a first part of the substrate fluid droplet pattern. In forming the first part of the substrate fluid droplet pattern, the fluid dispense head and the substrate move relative to each other in a translating direction. In a particular embodiment, the logic element can transmit information regarding the fluid droplet pattern and dispensing of the formable material to the fluid dispense head or a fluid dispense controller, or any combination thereof.

At block 630, the method can include moving the fluid dispense head in an offset direction perpendicular to the translating direction. In one embodiment, the fluid dispense head is moved in an offset direction while the fluid dispense head and substrate move relative to each other in the translating direction. In one embodiment, the offset direction is on the same plane as the substrate, the Y-direction. In another embodiment, the offset direction is on a different plane than the substrate, the Z-direction. In one embodiment, the fluid dispense head can move up increasing the distance between the fluid dispense ports and the substrate. In another embodiment, the fluid dispense head can move down decreasing the distance between the fluid dispense ports and the substrate. In yet another embodiment, the offset direction can be perpendicular to the translating direction both on the same plane as and in a different plane as the substrate, i.e. both the Y-direction and the Z-direction.

At block 640, the method can include dispensing formable material onto the substrate to form a second part of the substrate fluid droplet pattern. In one embodiment, as the second part of the fluid droplet pattern is dispensed, the fluid dispense head and substrate move relative each other in the translating direction. A substrate fluid dispense pattern can take many different shapes. An exemplary pattern includes a rectangular, grid pattern, a diamond pattern, another suitable pattern, or any combination thereof. In one embodiment, the fluid dispense head is moved in the offset direction in between dispensing the formable material to form the first part of the fluid droplet pattern and dispensing the formable material to form the second part of the fluid droplet pattern.

Further, the apparatus described above can be included in method of manufacturing an article. The method of manufacturing an article can include a device. In one embodiment, the device can be a semiconductor integrated circuit device, a liquid crystal display device, an electric circuit element—such as a volatile or nonvolatile semiconductor memory, DRAM, SRAM, flash memory, MRAM, LSI, a CCD, an image sensor, or an FPGA—an optical element, a MEMS, a printing element, a sensor, a mold, or the like. The method of manufacturing an article can include forming a pattern on a substrate using the above-described imprint apparatus. In one embodiment, the substrate can be a wafer, a glass plate, or a film-like substrate. The method can further include a processing step of the substrate on which the pattern was formed. In one embodiment, the processing step can include etching. In one embodiment, the pattern can be formed by contacting formable material with a template having a surface, curing the formable material to form a layer corresponding to the surface of the template, and forming a pattern on the substrate by the cured material on the substrate. The method of manufacturing can further include processing the substrate on which the pattern was formed and manufacturing the article from the processed substrate to form the device as described above.

Apparatus formed in accordance with embodiments herein can produce a droplet pattern that can be achieved by exceeding the manufacturing limitations of firing frequency and stage movement.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. An apparatus for imprint lithography comprising:
a fluid dispense head comprising at least two fluid dispense ports, wherein the at least two fluid dispense ports are in a fixed arrangement relative to one another;
a stage configured to hold a substrate, wherein the stage and the fluid dispense head are adapted to move the substrate and the at least two fluid dispense ports relative to each other; and
a logic element configured to:
transmit information to move the substrate relative to the fluid dispense head in a translating direction while performing the following steps:
transmit information to dispense a formable material onto the substrate to form a first part of the substrate fluid droplet pattern;
transmit information to move the fluid dispense head in an offset direction, wherein the offset direction is different than the translating direction, wherein the apparatus is configured to move the fluid dispense head after an instruction to dispense the formable material is executed; and
transmit information to dispense the formable material onto the substrate to form a second part of the substrate fluid droplet pattern, wherein the apparatus is configured to dispense the formable material after an instruction to move the fluid dispense head in the offset direction is executed, and wherein the first part of the fluid droplet pattern and the second part of the fluid droplet pattern are dispensed during a first pass.

2. The apparatus of claim 1, wherein the offset direction and the translating direction are in one plane parallel to the surface of the substrate.

3. The apparatus of claim 1, wherein the translating direction is in one plane parallel to the surface of the substrate and the offset direction is in a second plane different the one plane.

4. The apparatus of claim 1, wherein during dispensing, the fluid dispense head is oriented along a plane that is parallel to a surface of the substrate.

5. The apparatus of claim 1, wherein the at least two dispense ports have a fixed firing speed.

6. The apparatus of claim 1, wherein determining a substrate fluid drop pattern is for an imprint field.

7. The apparatus of claim 1, wherein the offset direction comprises a first offset direction and a second offset direction different from the first offset direction.

8. A method of generating a fluid droplet pattern on a substrate, the method comprising:
providing a fluid dispense head comprising at least two dispense ports, wherein the at least two fluid dispense ports are in a fixed arrangement relative to one another;
while moving the substrate relative to the fluid dispense head in a translating direction, the following steps are performed:
dispensing formable material onto the substrate to form a first part of the substrate fluid droplet pattern;
moving the fluid dispense head in an offset direction different from the translating direction after forming the first part of the substrate fluid droplet pattern; and
dispensing formable material onto the substrate to form a second part of the substrate fluid droplet pattern after moving the fluid dispense head in an offset direction, wherein the first part of the fluid droplet pattern and the second part of the fluid droplet pattern are dispensed during a first pass.

9. The method of claim 8, wherein the fluid dispense head is oriented along a plane that is parallel to a surface of the substrate.

10. The method of claim 8, wherein the offset direction and the translating direction are in one plane parallel to the surface of the substrate.

11. The method of claim 8, wherein the translating direction is in one plane parallel to a surface of the substrate and the offset direction is in a second plane different the one plane.

12. The method of claim 8, wherein in moving the fluid dispense head in the offset direction, the fluid dispense head moves in a first offset direction and in a second offset direction different from the first offset direction.

13. The method of claim 8, wherein determining a substrate fluid drop pattern is for an imprint field.

14. The method of claim 8, wherein the at least two dispense ports have a fixed firing speed.

15. The method of claim 8, wherein in moving the fluid dispense head in the offset direction, an offset amount of the fluid dispense head in the offset direction is less than a pitch between the two dispense ports of the fluid dispense head.

16. A method of manufacturing an article, the method comprising:
providing a fluid dispense head comprising a set of fluid dispense ports, wherein the fluid dispense ports are in a fixed arrangement relative to one another;
while moving the substrate relative to the fluid dispense head in a translating direction, the following steps are performed:
dispensing formable material onto the substrate to form a first part of the substrate fluid droplet pattern;
moving the fluid dispense head in an offset direction different from the translating direction after forming the first part of the substrate fluid droplet pattern;
dispensing formable material onto the substrate to form a second part of the substrate fluid droplet pattern after moving the fluid dispense head in an offset direction, wherein the first part of the fluid droplet pattern and the second part of the fluid droplet pattern are dispensed during a first pass;
contacting the formable material with a template having a surface;
curing the formable material to form a layer corresponding to the surface of the template;
forming a pattern on the substrate by the cured material on the substrate;
processing the substrate on which the pattern has been formed; and
manufacturing the article from the processed substrate.

17. A method of generating a fluid droplet pattern on a substrate, the method comprising:
providing a fluid dispense head comprising at least two dispense ports, wherein the at least two fluid dispense ports are in a fixed arrangement relative to one another;
while moving the fluid dispense head and the substrate relative to each other in a translating direction, the following steps are performed:
dispensing formable material onto the substrate to form a first part of the substrate fluid droplet pattern;
moving the fluid dispense head in an offset direction different from the translating direction to change a distance between the fluid dispense head and the substrate after forming the first part of the substrate fluid droplet pattern; and
dispensing formable material onto the substrate to form a second part of the substrate fluid droplet pattern after moving the fluid dispense head in an offset direction, wherein a pitch between the first part and the second part of the fluid droplet pattern is changed by changing the distance between the fluid dispense head and the substrate.

18. The method of claim 17, wherein the offset direction comprises a first offset direction and a second offset direction different from the first offset direction.

19. The method of claim 17, wherein the offset direction and the translating direction are in one plane parallel to the surface of the substrate.

20. The method of claim 17, wherein the translating direction is in one plane parallel to a surface of the substrate and the offset direction is in a second plane different the one plane.
